(19) United States
(12) Patent Application Publication
(10) Pub. No.: US 2011/0148480 A1
(43) Pub. Date: Jun. 23, 2011

(54) Divider with Enhanced Duty Cycle for Precision Oscillator Clocking Sources

(76) Inventor: Yongping Fan, Portland, OR (US)

(21) Appl. No.: 12/640,189

(22) Filed: Dec. 17, 2009

(51) Int. Cl. H03K 23/00

(52) U.S. Cl. 327/115

(57) ABSTRACT

A divider is disclosed that presents an enhanced duty cycle for use with precision oscillators in clock sources. In one example, the invention includes a first divider chain to receive an input clock and produce a first divided output, a second divider chain to receive the input clock and produce a second divided output, and a combiner to combine the first and second divided output to produce a third divided output with a duty cycle greater than the first and second divided output.

### FIELD

The present description relates to the field of clocks and clock circuits for integrated circuits and, in particular, to a divider with a desirable duty cycle.

### BACKGROUND

Integrated circuits (ICs) can require clock signals at a variety of different clock speeds or frequencies for internal processes, for different input/output (I/O) devices, and for external interfaces. Each clock is typically driven by a precision oscillator. To reduce power consumption and cost a single oscillator is typically combined with signal dividers to produce several different speeds using a single oscillator.

The choice of precision oscillator is important to the performance and cost of the integrated circuit. LCPLLs (LC Phase Locked Loops) provide high performance at reasonable cost for applications in which low jitter and high speed are desired. As industry is moving toward higher speed I/O (e.g. 5 GB and above), low jitter clocks become increasingly important. Compared to a typical self-biased differential ring oscillator type VCO (Voltage Controlled Oscillator), an LCVCO can offer one tenth the Kappa (a parameter reflecting jitter from thermal noise) at one fifth the power consumption. An LCPLL can also offer a much better power supply rejection ratio (PSRR).

On the other hand, an LCPLL can have a narrow frequency range, normally about 300 MHz. To extend the frequency range of an LCPLL, multiple LCVCOs can be used for each LCPLL. An LCPLL with more than two VCOs, however, is hard to design and requires a significant amount of chip area on an IC. Additional LCPLLs are expensive and difficult to design because each LCPLL requires precision inductors and capacitors. Accordingly, a single clock source with dividers is generally preferred. Digitally dividing the clock signal from the LCPLL is generally more efficient and less expensive.

### BRIEF DESCRIPTION OF THE DRAWINGS

Embodiments of the present invention are illustrated by way of example, and not limitation, in the figures of the accompanying drawings in which like reference numbers are used to refer to like features, and in which:

FIG. 1 is a block diagram of a divide-by-3 circuit device according to an embodiment of the present invention;

FIG. 2A is a graph of a 7.5 GHz clock pulse input that can be received by an embodiment of the present invention;

FIG. 2B is a graph of a 2.5 GHz clock pulse output with a 50% duty cycle that can be produced by the divide-by-three circuit of an embodiment of the present invention;

FIG. 3A is a graph of a 9.6 GHz clock pulse input that can be received by an embodiment of the present invention;

FIG. 3B is a graph of a 3.2 GHz clock pulse output with a 50% duty cycle that can be produced by the divide-by-three circuit of an embodiment of the present invention; and

FIG. 4 is a graph of internal node waveforms of a divide-by-three circuit according to an embodiment of the present invention.

### DETAILED DESCRIPTION

The frequency range of an LCPLL can be digitally extended to support multiple frequency targets and wide range continuous frequency applications with only one inductor. Divide by two circuits are used widely. There are many different divide by two circuits that produce a regular, even 50% duty cycle. Such a duty cycle is useful in many applications in which the leading and trailing edges of a pulse are both used as timing events. Divide by three circuits, on the other hand, naturally have a 33% duty cycle. This means that only one edge, either the leading edge or the trailing edge can be used as a timing event. However, a divide by three circuit with a 50% duty cycle is described below. This circuit can easily be combined with divide by two circuits making it simple and inexpensive to build. Several divide-by-two and divide-by-three circuits can be used together to provide divisions by 4, 6, 8, 9, 12, etc.

The divide by three circuit described below can provide a 50% duty cycle and is therefore useful for extending the frequency range of an LCPLL and of any other oscillator or clock signal. The circuit is constructed using flip-flops, inverters and NAND/NOR gates. Since these are well-understood components in different processes and material, the circuit can be designed into different types of electronic systems with high reliability. A 50% duty cycle can be achieved by adding two-overlapped divide-by-3 clock waves using an OR gate. The resulting clock signal can have a perfect 50% duty cycle, and be synchronized with the input clock.

Based on some tests, the average current consumption on one example design is 0.6 mA at 1.0V, and a 7.5 GHz input clock. The PSRR (power supply rejection ratio) is similar to conventional divide by two and divide by four circuits. The proposed divide-by-three circuit allows a single LCPLL with one VCO to support many different clock frequencies where otherwise two or more LCPLLs may be required.

Due to the simple design and the use of established logic gates, the described divide-by-three circuit can perform consistently across process, voltage, and temperature. The resulting wide frequency range of low jitter clocks may be applied to many different high speed I/O links, such as PCIE (Peripheral Component Interconnect Express) Generations 1, 2, and 3, QPI (Quick Path Interconnect), Ethernet and many others, as well as to internal clocks.

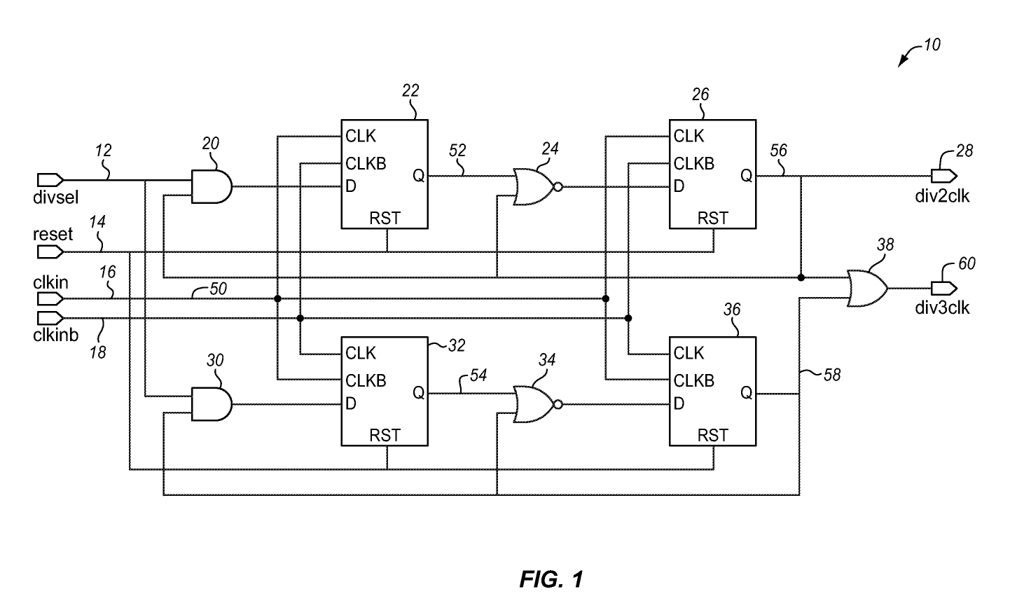

FIG. 1 shows an example schematic of one embodiment of a divide-by-three and divide-by-two combination circuit 10. It includes rising edge triggered flip-flops, NAND, and NOR gates, all from standard CMOS devices in digital technology. A 50% duty cycle is obtained by adding two-overlapped divide by 3 clock waves using an OR gate as explained below.

The circuit has four inputs, a divider select divsel input 12, a reset signal 14, a first clock input clkin 16 and a second clock input clkinb 18. Clkin and clkinb are high speed differential input clocks from, for example, an LCPLL or any other precision clock source. When the input control signal divsel is set to 0, a divide-by-2 clock can be obtained from the divide by two section of the circuit's output div2clk 28. When the divider selection input signal is set to 1, a divide-by-3 clock section of the circuit is selected and it provides an output from div3clk 30. Both outputs have approximately a 50% duty cycle.

The divsel signal is applied as an input to an AND gate 20. The output of the AND gate is applied to the D input of a first D-type flip flop 22. The Q output of the first flip flop is applied to a NOR gate 24. The output of the NOR gate is applied to a D input of a second D-type flip flop 26. The Q output of the second flip-flop is a divided-by-two version of the clock signal div2clk 28.

The two flip-flops are connected in series with the Q output of the first coupled to the D input of the second through a NOR gate. The series of two flip-flops together with the AND and NOR gates operate as a divide-by-two circuit that provides a 50% duty cycle at the output signal 28. To complete this circuit, both of the flip-flops 22, 26 have two clock inputs CLK, CLKB. These are supplied by the two differential clock inputs of the circuit clikin 16, clkinb 18, mentioned above. The reset input 14 into the circuit is applied to the RESET inputs of the two flip-flops. The AND and NOR gates both receive as their second input a feedback of the output div2clk signal 28.

With the divider selector 12 set to 0, first AND gate 20 will always have 0 as one of two inputs, the output of this gate will always be 0. Accordingly, the Q output of the first flip-flop will always be 0 to match the D input. The Q output is one of two inputs to the NOR gate 24. The output of the NOR gate will track the Q output of the second flip-flop 26. The second flip flop accordingly acts as if its Q output is coupled directly to its D input. It will then change states with every other falling edge of its clock input CLK 16. The result is a divide by two divider at the output div2clk 28. The output 60 of the divide by three section is not used in the divide-by-two mode.

FIG. 1 also has a lower signal chain or divider chain to complete the divide by three portion of the circuit. The lower section is identical to the upper section except for a change in the flip flops. In the upper signal chain, the flip-flops switch state in response to the rising edge of the clock. The flip-flops of the lower signal chain respond to the falling edge of the clock. The output of the lower signal chain 58 can also be used as a second divide-by-two output in the divide-by-two mode. The output will be out of phase from the upper output by the width of one clock pulse, or ninety degrees.

The divider selection signal 12 is also coupled to a second AND gate 30. The output of the AND gate is coupled as the D input to a third D-type flip flop 32. The Q output of the flip flop is coupled to a second NOR gate 34 as one of the inputs. The output of the NOR gate is coupled to the D input of a fourth flip flop 36. The Q output 58 of the fourth flip flop is applied as a feedback to the second inputs of the second AND and the second NOR gates.

The output of the fourth flip-flop 36 is also applied to an OR gate 38 which combines that signal with the output 56 of the upper divide by two section to obtain a divide by three output 60 with a 50% duty cycle. With the divider selector signal set to 1, both the upper and lower paths create divide by three signals. Combining the two divide by three signals 56, 58 at the OR gate 38 provides the divide by three output 60 with a 50% duty cycle.

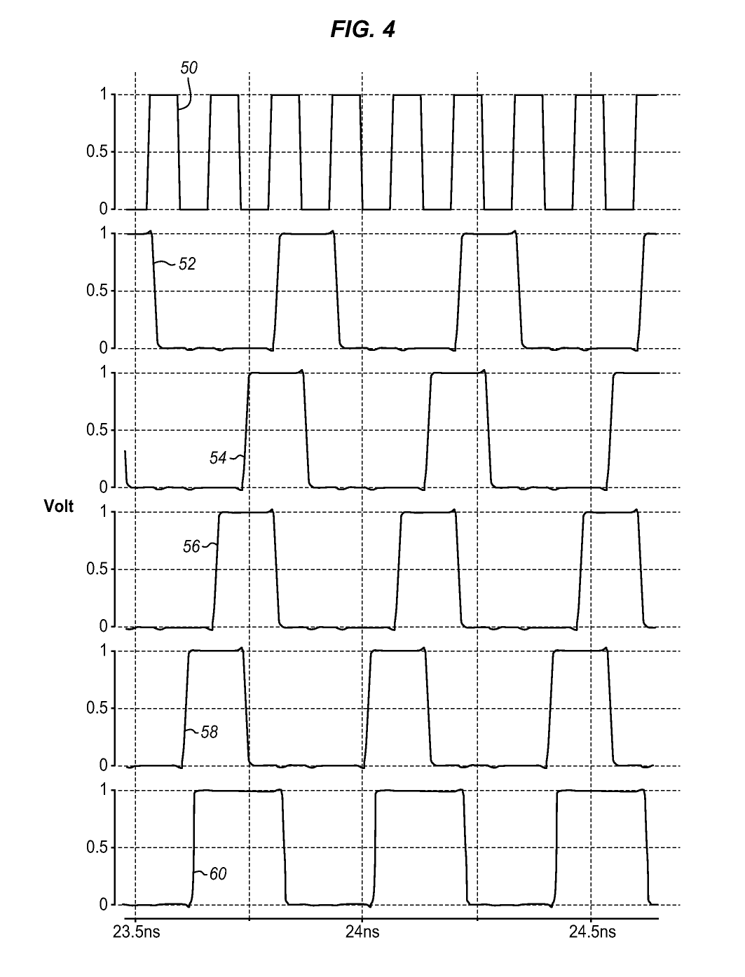

FIG. 4 is a diagram of example wave forms to illustrate the circuit of FIG. 1 in operation. FIG. 4 shows the internal node waveforms for a 7.5 GHz input clock 50. Waveforms 52 and 54 are outputs from the first flip-flop 22 (top-left in FIG. 1) and the third flip-flop 32 (bottom left in FIG. 1), respectively. Waveforms 56 and 58 are outputs from the second flip-flop 26 (top-right in FIG. 1) and the fourth flip-flop 36 (bottom right in FIG. 1), respectively. Signals 56 and 58 are inputs to the OR gate 38, where they are added to form the 50% duty cycle divide-by-3 clock 60.

The input clock, clkin is represented by the top wave form 50 in FIG. 5. This signal is produced by a stable oscillator such as an LCPLL or any other oscillator. All of the waveforms of FIG. 4 are plotted against voltage on the vertical axis and time on the horizontal axis. The voltage scale is shown as varying between zero and one volt, however, the particular voltage can be adapted to suit any particular application. Traditionally, zero volts corresponds to a low or binary zero input, while one volt corresponds to a binary one or high input. The time scale is shown as ranging from 23.5 ns to 25 ns from left to right. At the frequency of waveform 50, this scale corresponds to a frequency of 7.5 GHz, however, any other clock speed may be used. Only a few pulses are shown, however, the signals are typically produced for a long time.

Considered in more detail, the second waveform 52 corresponds to the output of the first flip-flop 22. At the first flip-flop at 23.5 ns, D is set low, but Q is high. D is low because the output 56 is low and the divsel 12 is high. Divsel remains high to select the divide by three mode. On the first rising edge of the input clock 60 after 23.5 ns, the Q output 52 of the flip-flop switches low to match D. The low is applied to the NOR gate 24 together with the low output signal 56 and D is set high to the flip flop 26. As a result on the next rising edge of the clock 50, the Q output of the second flip-flop 56 goes high. The high output is fed back to the logic gates at the D inputs of the two flip flops. As shown in FIG. 5, the Q output 56 of the second flip flop goes high every third rising edge of the clock. This output is a divide-by-three output with roughly a 33% duty cycle.

Considering the lower part of the circuit, the same combination of gates and flip flops is repeated. The first of the two lower flip-flops produces a Q output 54 shown in FIG. 5 and the second of the two lower flip-flops 36 produces a Q output 58 as shown in FIG. 5.

The difference between the upper part and the lower part of the circuit is that the upper two flip-flops 222, 26 are triggered by the rising edge of the clock pulse 50 and the lower two flip-flops 32, 36 are triggered by the falling edge of the clock pulse 50. As a result, the two Q outputs 56, 58 are spaced apart in time by the width of one clock pulse as shown in FIG. 5. In terms of the output pulse, the signals are sixty degrees out of phase.

Both signal paths or divider chains produce about a 33% duty cycle. Theoretically, the duty cycle of the two paths will be exactly one-third of the full cycle of the one-third clock rate signal. The actual duty cycle in any particular circuit will depend on the particular components used. The high portion of both signals is 120°, while the low portion is 240°. Adding the 60° leading portion of the lower path signal 58 to the 120° high portion of the upper path signal 56 provides a high portion of 180° which is half a cycle. When the two signals are combined a wider pulse is obtained that provides the desired 50% duty cycle.

In addition to a CMOS divide-by-three with 50% duty cycle circuit, a low swing (or current mode logic) circuit can also be constructed based on FIG. 1

The first logic gate 20, 30 of both divider chains acts as a function selector as mentioned above. In one mode, the input of the first flip-flop in each chain tracks the output of the chain. In the other mode, the input is always low, effectively disabling the first flip-flop in each chain. The mode is selected by applying the divsel signal 12 to an AND gate that also receives the output of the chain. This selection function can be achieved in other ways, however, depending on the particular application. The circuit can be constructed, for example, to completely bypass the first flip-flop in the divide-by-two mode. A different construction of logic gates can be used. Alternatively, the selection function can be removed by removing the two AND gates entirely.

As an alternative to the circuit configuration shown in FIG. 1, the upper and lower signal paths can be coupled to different clock inputs. FIG. 1 shows differential clock inputs 16, 18. Alternatively, if the circuit is provided with two clock inputs that differ in phase by 90° instead of 180°, then the first signal path can use one input while the second path uses the input that is 90° out of phase. If both paths use flip-flops that respond to the same portion of a clock pulse, either all flip-flops respond to a rising edge or all flip-flops respond to a trailing edge, then the same outputs can be produced as shown in FIG. 4.

As another alternative, both signal paths can be designed to change state on the same portion of the clock pulse, but the clock pulse to one of the divider chains can be delayed. So, for example a delay chain can be inserted in the clock signal path between the clock signal input and the clock inputs of the lower signal path.

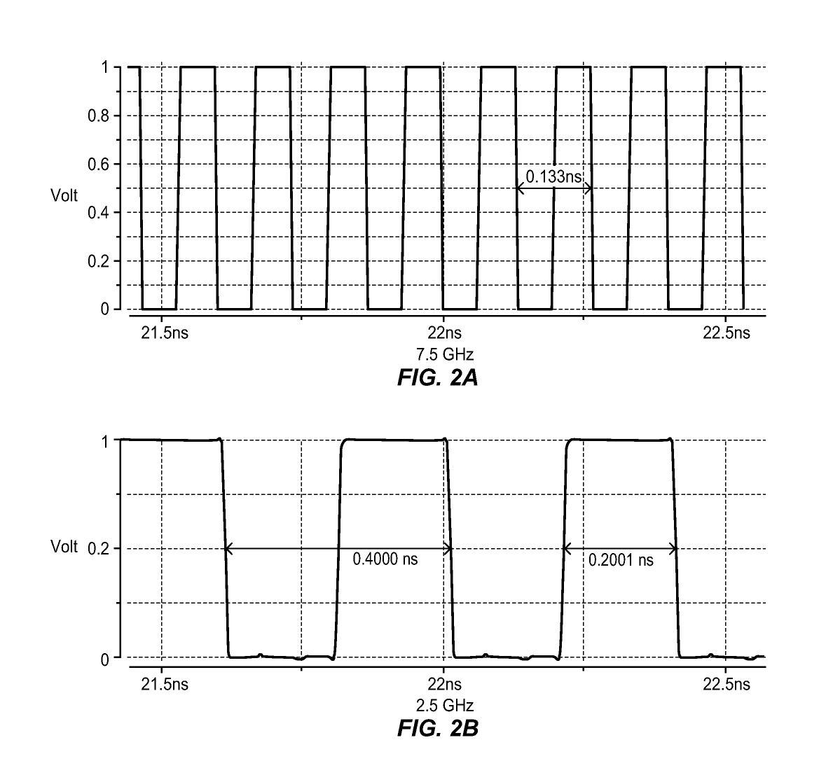

FIGS. 2A and 2B show waveforms that can be produced by the circuit of FIG. 1. While the circuit of FIG. 1 is theoretically capable of producing a perfect 50% duty cycle, simulations and physical test results introduce some inaccuracies. Nevertheless, the circuit of FIG. 1 is capable of coming very close to 50%.

FIG. 2A shows an input clock at 7.5 GHz, with a clock period of 0.1333 ns. As in FIG. 4, voltage is shown on the vertical axis and time on the horizontal axis. After being divided by 3 by the circuit of FIG. 1, the waveform of FIG. 2B is obtained at the divide-by-three output 60. The output clock is accordingly, about 2.5 GHz, with a period of about 0.400 ns. The width of each pulse is about 0.2001 ns. These results can be measured and simulated.

The duty cycle of the output clock can be determined as 200.1 ps/400 ps=50.025%. The specific values obtained will depend on the operating conditions of the circuit and the particular design of the circuit. The duty cycle numbers may be improved using custom designed gates are used, in which the rise and fall times can be matched more accurately.

A single precision oscillator capable of operating at 7.5 GHz and 8 GHz can be combined with a divide by two and a divide by three circuit to provide a wide range of different clock outputs. In one example, this combination can support PCIE G3 (4 GHz), G2 (2.5 GHz) and G1 (1.25 GHz) with a single VCO in an LCPLL. Without a divide-by-three circuit, two VCOs are required in the PLL. One PLL runs at 8 GHz, and the other runs at 5 GHz. Because the 7.5 GHz and 8 GHz speed are so close, a single PLL can be driving to either speed depending on the particular system needs at any one time. A LCVCO with frequency range of 7.5 GHz to 8 GHz can be easily designed. Using two VCOs costs design time and silicon area. Each VCO also requires additional inductors which are difficult to successfully manufacture.

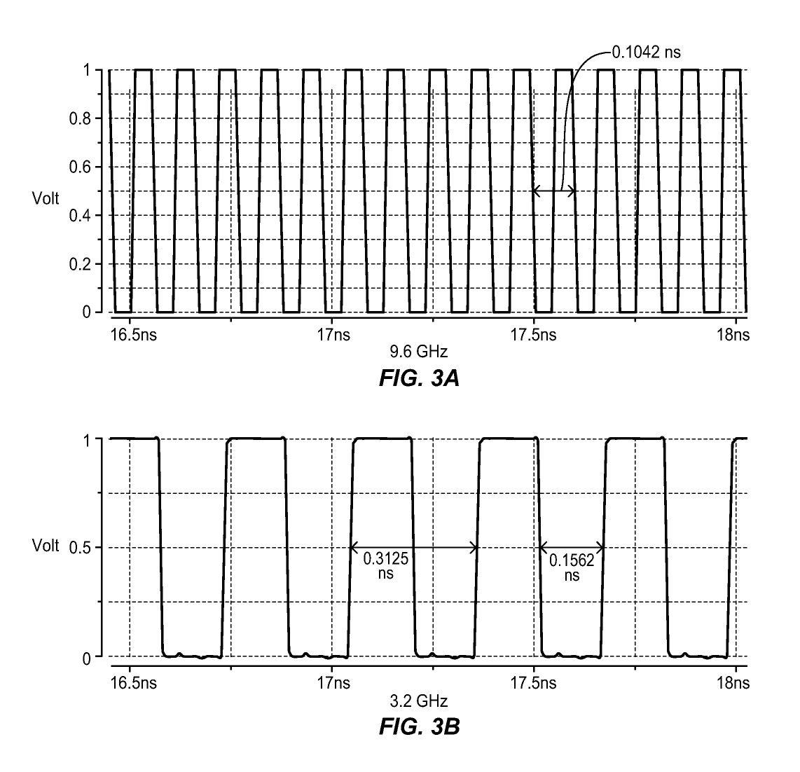

FIGS. 3A and 3B show another example use of the circuit of FIG. 1. In this case, the input clock of FIG. 3A is a 9.6 GHz or 0.1042 ns clock. Dividing this clock by three provides a 3.2 GHz or 0.3125 ns output clock. Using simulation for controlled typical operational conditions, a single pulse has been determined to be 0.1562 ns. This yields a duty cycle of 1562 ps/3125 ps for a duty cycle of 0.4998%. The precision of this result can be improved, as above, using custom designed logic gates and flip-flops.

At 9.6 GHz, a single LCPLL or other precision clock source can be combined with divide by two and divide by three dividers to support a high speed I/O link like QPI. This link requires clocks at 9.6 GT/s, 6.4 GT/s, and 3.2 GT/s. Conventionally, two VCOs would be required, one running at 9.6 GHz, and another running at 6.4 GHz.

Many modifications and variations are possible in light of the above teachings. Various equivalent combinations and substitutions may be made for various components and operations shown in the figures. The scope of the invention is not to be limited by this detailed description, but rather by the claims appended hereto.

The example logic gates, connections, frequencies and order of operations described above are provided only as examples. The configurations shown may be varied from implementation to implementation depending upon numerous factors, such as price constraints, performance requirements, technological improvements, or other circumstances. The components shown may be exchanged for their logical equivalents. Embodiments of the invention may be applied to a wide range of electronic devices and circuits with different clock requirements. The frequencies and formats listed are provided only as examples.

In the description above, numerous specific details are set forth. However, it is understood that embodiments of the invention may be practiced without these specific details. For example, well-known equivalent components may be substituted in place of those described herein. In addition, components may be removed or added to the illustrated circuit to improve results or add additional functions. In other instances, well-known circuits, structures and techniques have not been shown in detail to avoid obscuring the understanding of this description.

While the embodiments of the invention have been described in terms of examples, those skilled in the art may recognize that the invention is not limited to the embodiments described, but may be practiced with modification and alteration within the spirit and scope of the appended claims. The description is thus to be regarded as illustrative instead of limiting.

What is claimed is:

1. An apparatus comprising:
a first divider chain to receive an input clock and produce a first divided output;
a second divider chain to receive the input clock and produce a second divided output;
a combiner to combine the first and second divided output to produce a third divided output with a duty cycle greater than the first and second divided output.

2. The apparatus of claim 1, wherein the second divided output is out of phase from the first divided output.

3. The apparatus of claim 2, wherein the second divided output is out of phase by one clock pulse width from the first divided output.

4. The apparatus of claim 1, wherein the second divider chain receives the clock pulse out of phase from when the first divider chain receives the clock pulse.

5. The apparatus of claim 1, wherein the first divider chain changes state in response to a leading edge of the clock pulse and the second divider chain changes state in response to the trailing edge of the clock pulse.

6. The apparatus of claim 1, wherein the first and second divided outputs are divided by three with approximately a one-third duty cycle and wherein the first and second divided output are out of phase by about 60°.

7. The apparatus of claim 1, wherein the first and second divider chains each comprise two flip-flops coupled in series within the divider with the output of the second flip-flop producing the first and second divided output, respectively.

8. The apparatus of claim 7, further comprising a NOR gate between the two flip-flops, the NOR gate receiving as inputs, the output of the first flip-flop and the output of the second flip-flop.

9. The apparatus of claim 7, further comprising a selection gate wherein the first flip-flop of each divider chain is alternately connected in one mode or disconnected in another mode from the output of the second flip-flop.

10. The apparatus of claim 9, wherein the selection gate comprises an AND gate between the output of the second flip-flop and the input of the first flip-flop, the AND gate further being connected to a mode selection signal.

11. The apparatus of claim 9, wherein at least one divider chain function as a divide-by-three divider in the one mode and as a divide-by-two divider in the other mode.

12. The apparatus of claim 1, wherein the combiner is a logical OR gate.

13. A method comprising:
receiving a clock signal at a first frequency;
producing a first divided output with a second divided frequency and with a first duty cycle;
producing second divided output with the second divided frequency and the first duty cycle; and
combining the first and second output to produce a third divided output with the second divided frequency and with a second duty cycle longer than the first duty cycle.

14. The method of claim 12, wherein producing the second divided signal comprise producing the second divided signal out of phase with the first divided signal

15. The method of claim 12, wherein producing the first divided signal comprise producing the first divided signal based on a leading edge of the clock signal wherein producing the second divided signal comprise producing the second divided signal based on a trailing edge of the clock signal.

16. The method of claim 15, wherein the first duty cycle is about 33% and the second duty cycle is about 50%.
